(19) United States
(12) Patent Application Publication
(10) Pub. No.: US 2024/0109099 A1
(43) Pub. Date: Apr. 4, 2024

(54) WINDOW REINFORCING APPARATUS

(71) Applicant: Samsung Display Co., Ltd., Yongin-si (KR)

(72) Inventor: MINKI KIM, Yongin-si (KR)

(73) Assignee: Samsung Display Co., Ltd., Yongin-si (KR)

(21) Appl. No.: 18/348,507

(22) Filed: Jul. 7, 2023

(30) Foreign Application Priority Data
Sep. 30, 2022 (KR) 10-2022-0125149

(51) Int. Cl. B05C 21/00; B05B 1/14; B05B 15/20

(52) U.S. Cl. CPC B05C 21/005; B05B 1/14; B05B 15/20; G02B 1/10

(57) ABSTRACT

A window reinforcing apparatus includes a spray part which sprays a solution downward, a plurality of masks which are disposed below the spray part and move in a first direction, a storage part which is disposed above the spray part, stores the solution, and provides the solution to the spray part, and a stage disposed below the masks.

### CROSS-REFERENCE TO RELATED APPLICATIONS

This U.S. non-provisional patent application claims priority to and benefits of Korean Patent Application No. 10-2022-0125149 under 35 U.S.C. § 119, filed in the Korean Intellectual Property Office (KIPO) on Sep. 30, 2022, the entire contents of which are incorporated herein by reference.

### BACKGROUND

The disclosure herein relates to a window reinforcing apparatus.

In general, a display device includes a display panel, which includes pixels to display an image, and a window, which is disposed on the display panel to protect the display panel. The window may include glass or a transparent plastic material.

The window protects the display panel from external scratches and impacts. The window is attached to the display panel by an adhesive. The image generated in the display panel passes through the window and is provided to the user.

Recently, windows made of ultra-thin glass are used in foldable display devices. A window made of ultra-thin glass may be damaged during bending, and thus, there is a need to develop a technique for reinforcing the window made of ultra-thin glass.

### SUMMARY

The disclosure provides a window reinforcing apparatus for reinforcing a window.

The technical objectives to be achieved by the disclosure are not limited to those described herein, and other technical objectives that are not mentioned herein would be clearly understood by a person skilled in the art from the description of the disclosure.

An embodiment of the disclosure provides a window reinforcing apparatus including a spray which sprays a solution downward; a plurality of masks which are disposed below the spray part and move in a first direction; a storage part which is disposed above the spray part, stores the solution, and provides the solution to the spray part; and a stage disposed below the masks.

The window reinforcing apparatus may further comprise at least one ultrasonic wave-generating part disposed on an outer wall of the storage part.

The window reinforcing apparatus may further comprise a stirrer which is disposed on a bottom surface of the storage part in an inner space of the storage part and rotates.

The spray part may comprise an accommodation part which has a flat plate shape defined by the first direction and a second direction intersecting the first direction and stores the solution provided from the storage part; and a plurality of nozzles which are disposed below the accommodation part and spray the solution downward.

The nozzles may be arranged in the first direction and the second direction.

The solution may be sprayed at a certain spray angle from each of the nozzles, and the plurality of masks may be disposed to overlap regions in which the solutions sprayed from the nozzles overlap each other in a plan view.

The plurality of masks may comprise a first mask and a second mask which are arranged in the first direction and move in the first direction, and the solution sprayed from the spray part may pass through between the first mask and the second mask which move away from each other in the first direction, and is provided to a window disposed on the stage.

The stage may heat the window to a temperature in a range of about 150 degrees to about 180 degrees.

The solution may comprise a solvent; and a reinforcing agent dissolved in the solvent.

The solvent may comprise a water, and the reinforcing agent may comprise a potassium nitrate.

The window reinforcing apparatus may further comprise a plurality of binders precipitated in the solution, wherein the plurality of binders may comprise a plurality of metal oxide particles.

In case that the solution is provided on a surface of the window, the solvent may be evaporated, and the surface of the window may be coated with the reinforcing agent.

A thickness of the reinforcing agent provided on the surface of the window may be reduced gradually from a central portion of the window toward sides of the window in the first direction.

The window reinforcing apparatus may further comprise a camera which is disposed above the stage and captures an image of the surface of the window coated with the reinforcing agent.

The window reinforcing apparatus may further comprise a heating chamber in which the window coated with the reinforcing agent is disposed and the reinforcing agent is heated to a temperature in a range of about 370 degrees to about 420 degrees.

Compressive stress of the window may be determined by the following equation, CS(x)=(L−2x)/2V(x) where x represents an X-axis coordinate value spaced apart from a center point of the window with respect to the first direction, the X axis is defined as extending in the first direction on the surface of the window, CS represents the compressive stress, L represents a length of the window in the first direction, and V represents speeds of the first and second masks.

The window reinforcing apparatus may further comprise a plurality of suction parts disposed above the first and second masks.

The spray part may comprise a plurality of nozzles that spray the solution toward the window, and in case that the first mask and the second mask may move away from each other in the first direction, the solution may be sprayed sequentially from the nozzles exposed between the first mask and the second mask.

The window reinforcing apparatus may further comprise a partition wall which is disposed on an edge of the spray part and extends toward the first and second masks.

In an embodiment of the disclosure, a window reinforcing apparatus includes a spray part which sprays a solution having a reinforcing agent downward; a first mask and a second mask which are disposed below the spray part and move in a first direction; and a stage disposed below the first and second masks, wherein the solution sprayed from the spray part passes through between the first mask and the second mask, which move away from each other in the first direction, and is provided to a window disposed on the stage, and a thickness of the reinforcing agent provided on a surface of the window is reduced gradually from a central portion of the window toward sides of the window in the first direction.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic view showing a configuration of a window reinforcing apparatus according to an embodiment of the disclosure;

FIG. 2 is a schematic cross-sectional view taken along line I-I′ of FIG. 1;

FIG. 3 is a schematic view showing components of a solution illustrated in FIG. 2;

FIG. 4 is a schematic view illustrating the lower surface of a spray part illustrated in FIG. 1;

FIG. 5 is a schematic cross-sectional view taken along line II-IT of FIG. 1;

FIGS. 6 to 9 are schematic views for explaining a coating process using the window reinforcing apparatus illustrated in FIG. 1;

FIG. 10 is a schematic view showing a state in which a camera illustrated in FIG. 1 is disposed above a stage;

FIG. 11 is a schematic view showing a configuration of a window reinforcing apparatus for a window reinforcing process;

FIGS. 12 and 13 are schematic views for explaining the reinforcing process of the window illustrated in FIG. 11;

FIG. 14 is a view illustrating a graph of the compressive stress formed on the surface of the window;

FIG. 15 is a schematic view illustrating a display device that includes the window manufactured by the window reinforcing apparatus including the components illustrated in FIGS. 1 to 11;

FIG. 16 is a schematic view illustrating a folding state of the display device illustrated in FIG. 15;

FIG. 17 is a schematic view illustrating, as an example, the cross-section of the display device illustrated in FIG. 15;

FIG. 18 is a schematic view illustrating a folding state of the window illustrated in FIG. 17;

FIG. 19 is a schematic view showing a configuration of a window reinforcing apparatus according to an embodiment of the disclosure; and

FIGS. 20 to 22 are schematic views showing operations of a window reinforcing apparatus according to an embodiment of the disclosure.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. It may also be understood that if one part and another part are connected, they may or may not be integral with each other.

Like references numbers and/or references characters refer to like elements throughout. Also, in the drawings, the thicknesses, ratios, and dimensions of the elements may be exaggerated for effective description of the technical contents.

The term “and/or” includes all combinations of one or more of which associated configurations may define. For example, “A and/or B” may be understood to mean “A, B, or A and B.”

Although the terms “first,” “second,” and the like may be used herein to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, embodiments of the disclosure will be described with reference to the drawings.

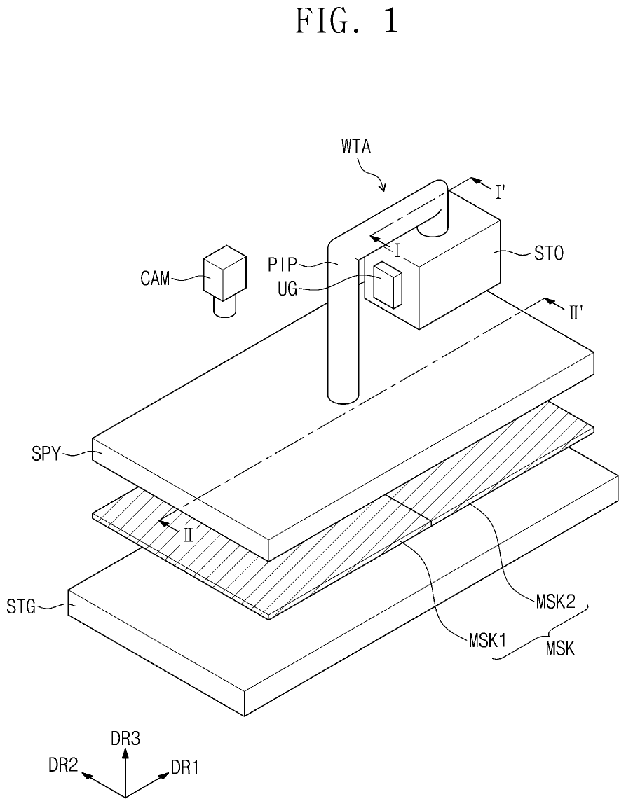

FIG. 1 is a schematic view illustrating a configuration of a window reinforcing apparatus according to an embodiment of the disclosure.

Referring to FIG. 1, a window reinforcing apparatus WTA according to an embodiment of the disclosure may include a storage part (or storage) STO, an ultrasonic wave-generating part (or generator) UG, a pipe PIP, a spray part SPY, masks MSK, a stage STG, and a camera CAM.

The storage part STO may be disposed above the spray part SPY. The storage part STO may have a hexahedral shape. The storage part STO may store a solution. The solution may include a reinforcing agent that is provided on a window to reinforce the window, which will be described below. The solution will be described below in detail.

The storage part STO may provide the solution to the spray part SPY. For example, the pipe PIP may be connected and/or extended to the storage part STO. For example, the pipe PIP may be connected to the upper surface of the storage part STO, but the embodiment of the disclosure is not limited thereto. The pipe PIP may be connected to the side surface of the storage part STO or the lower surface of the storage part STO.

The pipe PIP may extend toward the spray part SPY and be disposed on the spray part SPY. The pipe PIP may be connected to the spray part SPY. For example, the pipe PIP may be connected to the upper surface of the spray part SPY. The solution stored in the storage part STO may be provided to the spray part SPY via the pipe PIP.

The ultrasonic wave-generating part UG may be disposed on the outer wall of the storage part STO. For example, the ultrasonic wave-generating part UG may be connected to the side surface of the storage part STO. The ultrasonic wave-generating part UG may generate ultrasonic waves.

The ultrasonic waves generated in the ultrasonic wave-generating part UG may be transmitted into the storage part STO. The function of the ultrasonic wave-generating part UG will be described below in detail. For example, the ultrasonic wave-generating part UG may be disposed on the side surface of the storage part STO, but the embodiment of the disclosure is not limited thereto. The ultrasonic wave-generating part UG may be disposed on the upper surface of the storage part STO or the lower surface of the storage part STO.

The spray part SPY may have a flat plate shape defined by a first direction DR1 and a second direction DR2 intersecting the first direction DR1. For example, the spray part SPY may have a rectangular shape that extends longer in the first direction DR1 than in the second direction DR2. The spray part SPY may receive the solution from the storage part STO via the pipe PIP. The spray part SPY may spray the solution, provided from the storage part STO, downward.

Hereinafter, a third direction DR3 may be defined as a direction that is substantially perpendicular to the plane defined by the first direction DR1 and the second direction DR2. Also, in this description, the expression “when viewed in a plan view” or “in a plan view” may mean a state when viewed in the third direction DR3.

Masks MSK1 and MSK2 may be disposed below the spray part SPY. Each of the masks MSK1 and MSK2 may have a flat plate shape defined by the first direction DR1 and the second direction DR2. The masks MSK1 and MSK2 may be arranged in the first direction DR1. The masks MSK1 and MSK2 may move in the first direction DR1.

The masks MSK1 and MSK2 may include a first mask MSK1 and a second mask MSK2 adjacent to the first mask MSK1 in the first direction DR1. The first mask MSK1 and the second mask MSK2 may reciprocate in the first direction DR1.

The stage STG may be disposed below the masks MSK1 and MSK2. The stage STG may have a flat plate shape defined by the first direction DR1 and the second direction DR2. For example, the stage STG may have a rectangular shape that extends longer in the first direction DR1 than in the second direction DR2.

A window may be disposed on the stage STG and will be described below. The stage STG may be defined as a heating stage STG that applies heat to the window. This configuration will be described below in detail.

The camera CAM may be disposed above the stage STG. After a process of coating a window disposed on the stage STG is completed, the camera CAM may be used to capture an image of a reinforcing agent that has been applied on the window. This will be described below. This configuration will be described below in detail.

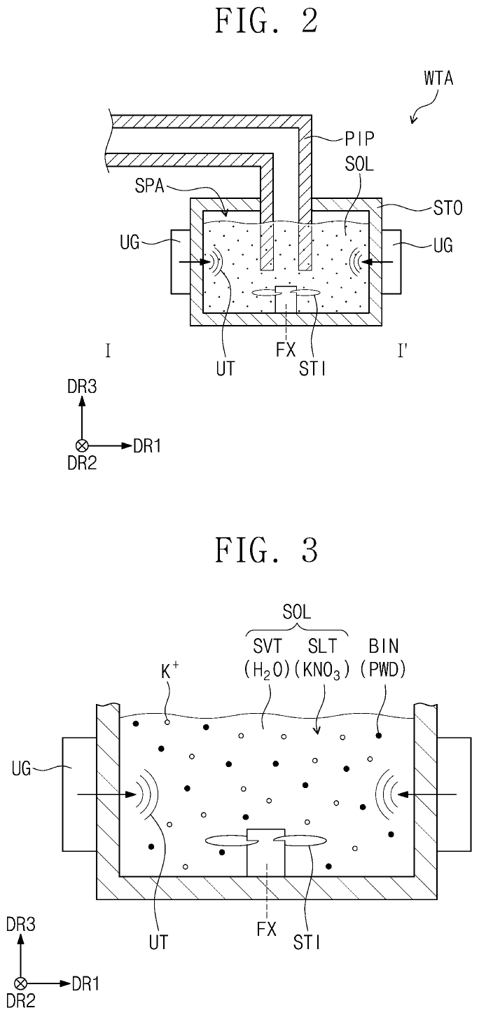

FIG. 2 is a schematic cross-sectional view taken along line I-I′ of FIG. 1. FIG. 3 is a schematic view illustrating components of the solution illustrated in FIG. 2.

For example, FIG. 2 illustrates a portion of the pipe PIP connected to the storage part STO and the ultrasonic wave-generating part UG connected to the storage part STO together with the storage part STO. The pipe PIP may be omitted in FIG. 3.

Referring to FIGS. 1 and 2, an inner space SPA may be defined inside the storage part STO. A solution SOL may be present in the inner space SPA of the storage part STO. The end of the pipe PIP may extend to the inner space SPA of the storage part STO and may be disposed within the solution SOL.

The window reinforcing apparatus WTA may include ultrasonic wave-generating parts UG and a stirring part STI (e.g., stirrer, agitator, and/or mixer, and it is referred to as a stirrer in an embodiment of the disclosure). The ultrasonic wave-generating parts UG may be disposed on sides of the storage part STO that are opposite to each other in the first direction DR1. However, the embodiment of the disclosure is not limited thereto. Although not illustrated, additional ultrasonic wave-generating parts UG may be further disposed on sides of the storage part STO that are opposite to each other in the second direction DR2.

The ultrasonic wave-generating parts UG may be connected to sides of the storage part STO and generate ultrasonic waves UT. The ultrasonic waves UT may be transmitted to the solution SOL of the inner space SPA and vibrate the solution SOL.

The stirrer STI may be disposed on the bottom surface of the storage part STO in the inner space SPA. The stirrer STI may be connected to the bottom surface of the storage part STO. The stirrer STI may rotate about a rotation axis FX parallel to the third direction DR3. The stirrer STI may stir the solution SOL while rotating.

Referring to FIG. 3, the solution SOL may include a solvent SVT and a solute SLT. The solvent SVT may include water (H₂O). The solute SLT may include potassium nitrate (KNO₃). The potassium nitrate (KNO₃) may be dissolved in the water (H₂O). As the potassium nitrate (KNO3) is dissolved in the water (H₂O), the solution SOL may include potassium ions (K⁺).

The potassium nitrate (KNO₃) dissolved in the water (H₂O) is not illustrated as a separate image, but the potassium ions (K⁺) are illustrated as circular shapes. Hereinafter, the solute SLT including the potassium nitrate (KNO₃) may be referred to as a reinforcing agent.

Binders BIN may be precipitated in the solution SOL. For example, the binders BIN may be mixed with the solution SOL. The binders BIN may include metal oxide particles PWD. The metal oxide particles PWD may be defined as metal powders. The metal oxide particles PWD may include, e.g., at least one of TiO₂, ZnO, ZrO₂, and Al₂O₃. For example, FIG. 3 illustrates the metal oxide particles PWD as small circular shapes filled with a black color. However, the embodiments are not limited thereto.

The solution SOL may be formed by dissolving the potassium nitrate (KNO₃) in the water (H₂O). The solution SOL mixed with the metal oxide particles PWD may be defined as a suspension or slurry.

The ultrasonic waves UT generated in the ultrasonic wave-generating part UG may be transmitted to the solution SOL and vibrate the solution SOL. This vibration may uniformly distribute the metal oxide particles PWD in the solution SOL.

As the stirrer STI stirs the solution SOL while rotating about the rotation axis FX, the metal oxide particles PWD may be more uniformly distributed in the solution SOL. For example, the ultrasonic wave-generating part UG and the stirrer STI may be used to more uniformly mix the metal oxide particles PWD with the solution SOL.

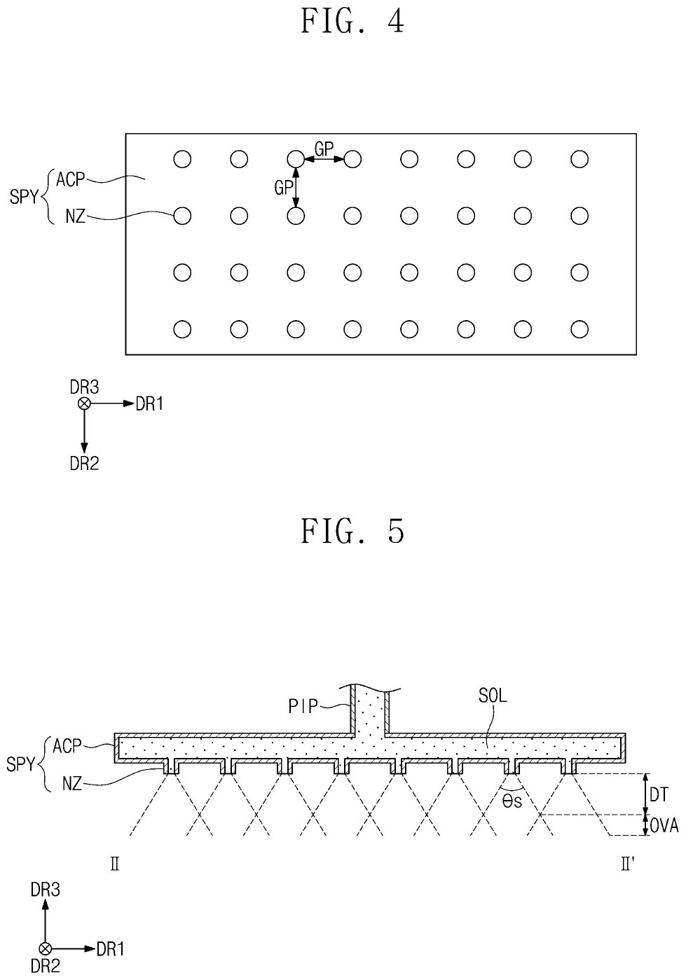

FIG. 4 is a schematic view illustrating the lower surface of the spray part illustrated in FIG. 1. FIG. 5 is a schematic cross-sectional view taken along line II-IT of FIG. 1.

For example, FIG. 5 illustrates a portion of the pipe PIP connected to the spray part SPY together with the spray part SPY.

Referring to FIGS. 4 and 5, the spray part SPY may include an accommodation part ACP and nozzles NZ arranged below the accommodation part ACP. The accommodation part ACP may have a flat plate shape defined by the first direction DR1 and the second direction DR2. The accommodation part ACP may have a rectangular shape that extends longer in the first direction DR1 than in the second direction DR2.

The pipe PIP may be connected to the accommodation part ACP. The pipe PIP may be connected to the upper surface of the accommodation part ACP. The accommodation part ACP may receive the solution SOL from the storage part STO via the pipe PIP. The accommodation part ACP may accommodate the solution SOL provided from the storage part STO.

The nozzles NZ may be connected to a lower portion of the accommodation part ACP. The nozzles NZ may have circular shapes in a plan view, but the shapes of the nozzles NZ are not limited thereto. The nozzles NZ may be arranged in the first direction DR1 and the second direction DR2. Therefore, the nozzles NZ may be arranged in the form of matrix. For example, the nozzles NZ may be arranged at equal intervals GP in the first direction DR1 and arranged at equal intervals GP in the second direction DR2.

The nozzles NZ may receive the solution SOL from the accommodation part ACP and spray the solution SOL downward. The nozzles NZ may spray the solution SOL at a certain spray angle θₛ. The solution SOL sprayed from the nozzles NZ in regions adjacent to the nozzles NZ may be sprayed downward without overlapping each other in a view or direction (e.g., in a plan view).

Depending on the spray angle θₛ, solutions SOL sprayed downward from the nozzles NZ may overlap each other from a certain distance DT. The distance DT may be defined as a distance spaced downward from the lower surfaces of the nozzles NZ.

Hereinafter, the region, in which the solutions SOL sprayed downward from the nozzles NZ overlap each other, may be defined as an overlapping region OVA. The solutions SOL sprayed from the nozzles NZ may merge with each other in the overlapping region OVA and be sprayed downward together.

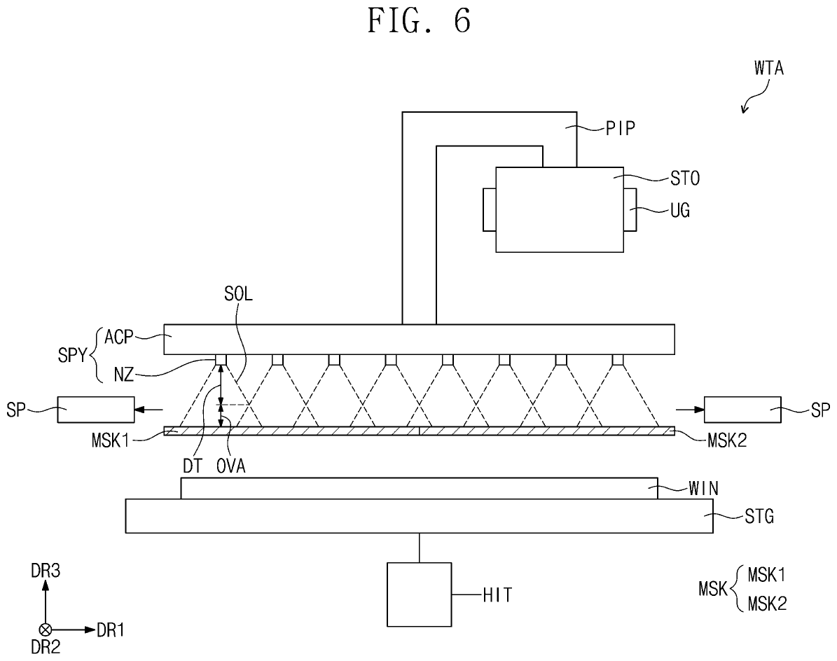

FIGS. 6 to 9 are schematic views for explaining a coating process using the window reinforcing apparatus illustrated in FIG. 1.

For example, FIGS. 6 to 9 illustrate side surfaces of the window reinforcing apparatus WTA when the window reinforcing apparatus WTA is viewed in the second direction DR2.

Referring to FIG. 6, a window WIN may be disposed on the stage STG. The window WIN may include glass. The window WIN may be defined as ultra-thin glass.

The window reinforcing apparatus WTA may include a heater HIT. The heater HIT may be disposed below the stage STG. The heater HIT may be connected to the stage STG and heat the stage STG. The heat of the stage STG may be transmitted to the window WIN and heat the window WIN. For example, the heater HIT may be disposed outside the stage STG, but the embodiment of the disclosure is not limited thereto. The heater HIT may be disposed inside the stage STG and heat the stage STG.

The first mask MSK1 and the second mask MSK2 may be arranged in the first direction DR1 and adjacent to each other. The first mask MSK1 and the second mask MSK2 may be arranged above the window WIN. For example, a side of the first mask MSK1 and a side of the second mask MSK2, which face each other in the first direction DR1, may be arranged to contact each other at the beginning of the process.

The spray part SPY may be disposed above the first and second masks MSK1 and MSK2. The nozzles NZ may be arranged to face the first and second masks MSK1 and MSK2.

The solution SOL may be provided to the spray part SPY from the storage part STO disposed above the spray part SPY. The solution SOL may be provided to the spray part SPY via the pipe PIP. The solution SOL may be accommodated in the accommodation part ACP and sprayed downward via the nozzles NZ.

The first and second masks MSK1 and MSK2 may be arranged in the overlapping region OVA. For example, the first and second masks MSK1 and MSK2 may be arranged to overlap the overlapping region OVA in which the solutions SOL sprayed from the nozzles NZ are sprayed to overlap each other. The solutions SOL sprayed from the nozzles NZ may be mixed with each other in the overlapping region OVA and more uniformly sprayed downward in the overlapping region OVA.

The window reinforcing apparatus WTA may further include suction parts SP. The suction parts SP may be arranged above the first mask MSK1 and the second mask MSK2. The suction parts SP may be adjacent to the first mask MSK1 and the second mask MSK2. In case that the first mask MSK1 and the second mask MSK2 contact each other, the suction parts SP may be arranged outside the first mask MSK1 and the second mask MSK2.

The suction parts SP may generate suction force (for example, indicated by an arrow). The solutions SOL sprayed outward from the first mask MSK1 and the second mask MSK2 may be suctioned and removed by the suction parts SP.

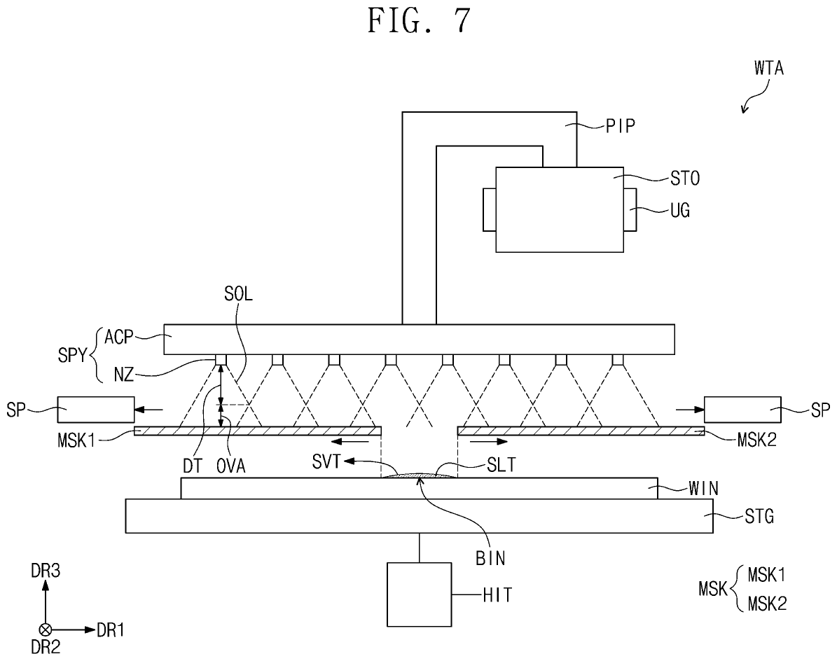

Referring to FIG. 7, the first mask MSK1 and the second mask MSK2 may move in the first direction DR1. The first mask MSK1 and the second mask MSK2 may move away from each other in the first direction DR1.

The solution SOL sprayed from the spray part SPY may pass through between the first mask MSK1 and the second mask MSK2 which move away from each other in the first direction DR1, and may be provided to a window WIN disposed on the stage STG. The solution SOL may be provided on the upper surface of the window WIN.

The stage STG may be heated to a temperature in a range of about 150 degrees to about 180 degrees by the heater HIT. Therefore, the window WIN may be heated to a temperature in a range of about 150 degrees to about 180 degrees by the stage STG.

In case that the solution SOL is provided on the window WIN, the solvent SVT may be evaporated by the heated window WIN, and the reinforcing agent SLT, which is the solute SLT, may remain on the window WIN. Therefore, the top surface of the window WIN may be coated with the reinforcing agent SLT.

The binders BIN may serve to ensure that the reinforcing agent SLT is well adsorbed on the surface of the window WIN. For example, the potassium nitrate (KNO₃) of the reinforcing agent SLT may be well attached to the surface of the window WIN by the metal oxide particles PWD of the binders BIN. Therefore, the window WIN may be well coated with the reinforcing agent SLT.

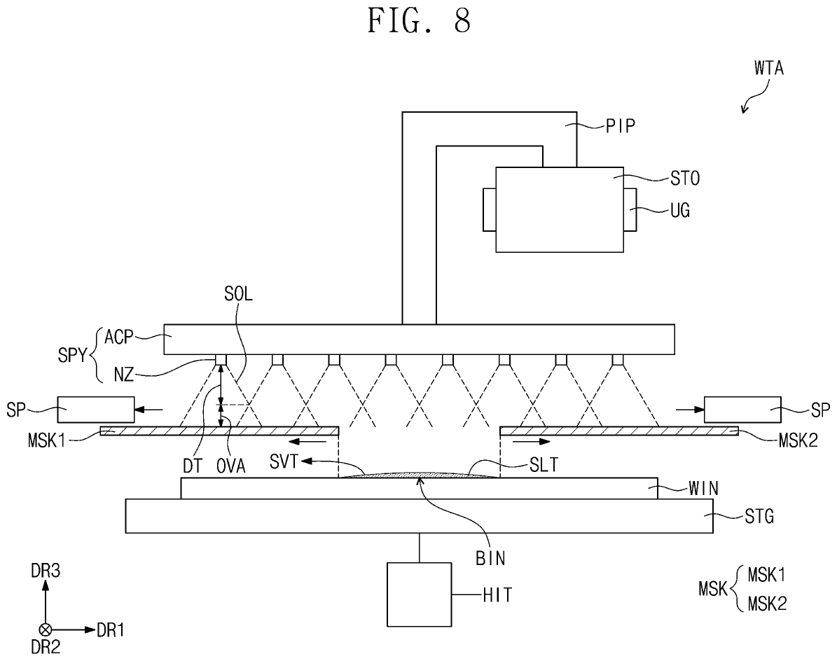

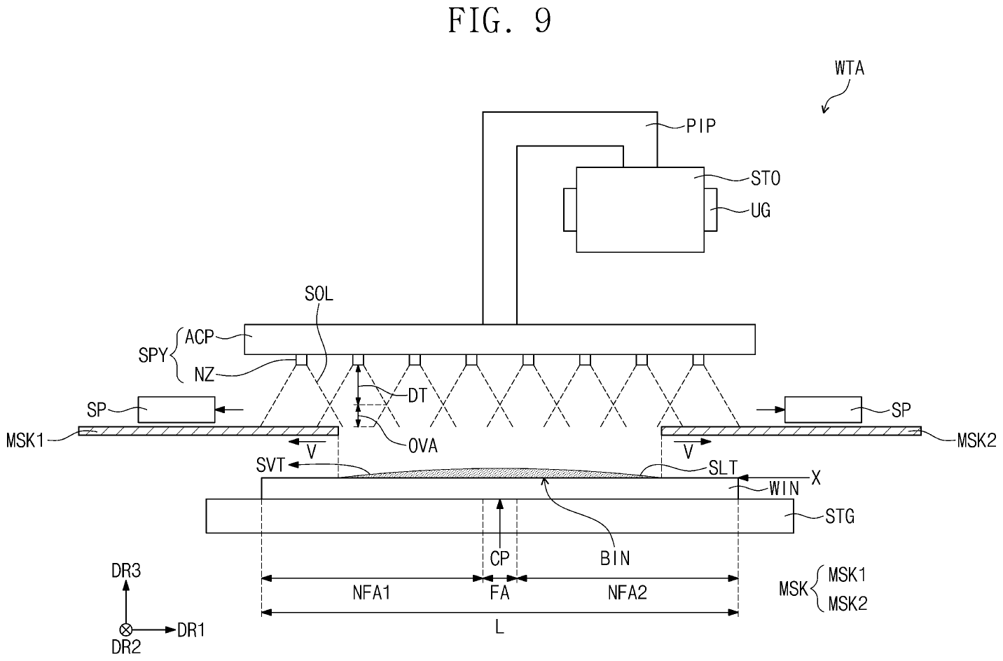

Referring to FIGS. 8 and 9, the first mask MSK1 and the second mask MSK2 may move gradually away from each other in the first direction DR1. The solution SOL sprayed from the spray part SPY may pass through between the first mask MSK1 and the second mask MSK2 and be provided on the upper surface of the window WIN. As described above, the solvent SVT may be evaporated by the heated window WIN, and the surface of the window WIN may be coated with the reinforcing agent SLT.

The first mask MSK1 and the second mask MSK2 may move away from each other in the first direction DR1. Therefore, the largest amount of the solution SOL may be provided at a central portion of the window WIN, and the amount of the solution SOL to be provided may be gradually reduced toward the edges of the window WIN. The edges of the window WIN may represent sides of the window WIN that are opposite to each other in the first direction DR1. The thickness of the reinforcing agent SLT provided on the surface of the window WIN may be gradually reduced from the central portion of the window WIN toward the sides of the window WIN in the first direction DR1.

The central portion of the window WIN may be defined as a folding region FA in the first direction DR1. A first non-folding region NFA1 and a second non-folding region NFA2 of the window WIN may be arranged on sides of the folding region FA, respectively. The folding region FA may be disposed between the first non-folding region NFA1 and the second non-folding region NFA2. The first non-folding region NFA1, the folding region FA, and the second non-folding region NFA2 may be arranged in the first direction DR1.

The larger amount of the reinforcing agent SLT may be applied to the folding region FA than the first and second non-folding regions NFA1 and NFA2. The folding region FA may be folded in a display device, and this configuration will be described below in detail.

A center point CP of the window WIN may be defined in the first direction DR1. An X axis X having the center point CP as the center may be defined. For example, the X axis X may be defined as overlapping the upper surface of the window WIN.

The coating amount of the reinforcing agent SLT applied to the surface of the window WIN may correspond to the thickness of the reinforcing agent SLT applied to the surface of the window WIN. The coating amount of the reinforcing agent SLT applied to the surface of the window WIN may be expressed by Equation (1).

CT(x)=(L−2x)/2V(x) (1)

where x may represent an X-axis coordinate value spaced apart from the center point CP of the window WIN in the first direction DR1, and the X axis X may be defined as extending in the first direction DR1 on the surface of the window WIN.

CT may represent the coating amount of the reinforcing agent SLT. CT(x) may represent the coating amount of the reinforcing agent SLT applied at the position of the corresponding coordinate. L may represent the length of the window WIN in the first direction DR1. V may represent speeds of the first and second masks MSK1 and MSK2. V(x) may represent the speeds of the first and second masks MSK1 and MSK2 at the corresponding X-axis coordinate value.

Depending on (L−2x) corresponding to the numerator in Equation (1), the coating amount of the reinforcing agent SLT may be reduced with distance from the center point CP. Depending on 2V(x) corresponding to the denominator in Equation (1), the coating amount of the reinforcing agent SLT may be reduced as the speeds of the first and second masks MSK1 and MSK2 increase. As the speeds of the first and second masks MSK1 and MSK2 are reduced, the coating amount of the reinforcing agent SLT may increase.

In the embodiment of the disclosure, the coating amount (or thickness) of the reinforcing agent SLT applied to the surface of the window WIN may be controlled according to the speeds of the first and second masks MSK1 and MSK2.

The process illustrated in FIGS. 6 to 9 may be defined as a process for coating the window WIN.

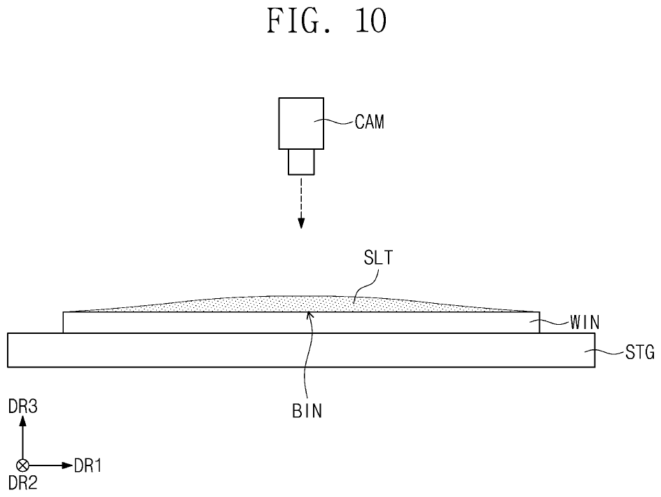

FIG. 10 is a schematic view illustrating a state in which the camera illustrated in FIG. 1 is disposed above the stage.

Referring to FIG. 10, the camera CAM may be disposed above the window WIN. In case that the reinforcing agent SLT is applied to the window WIN, the binders BIN making the reinforcing agent SLT adsorbed on the surface of the window WIN may also be disposed on the surface of the window WIN. Similar to the reinforcing agent SLT, the amount of the binders BIN provided on the surface of the window WIN may also be reduced from the center of the window WIN toward sides of the window WIN.

In general, the metal oxide particles may have a certain color. Therefore, the binders BIN including the metal oxide particles may have a certain color. This color may be darker in case that the binders BIN are accumulated thicker, but may be lighter in case that the binders BIN are accumulated thinner. Therefore, in case that the camera CAM captures an image of the surface of the window WIN coated with the reinforcing agent SLT, the coating thickness of the reinforcing agent SLT may be measured.

After the coating process of the reinforcing agent SLT, the coating thickness of the reinforcing agent SLT may be checked by the image captured by the camera CAM. Accordingly, it may be confirmed whether the coating thickness of the reinforcing agent SLT is normal or not.

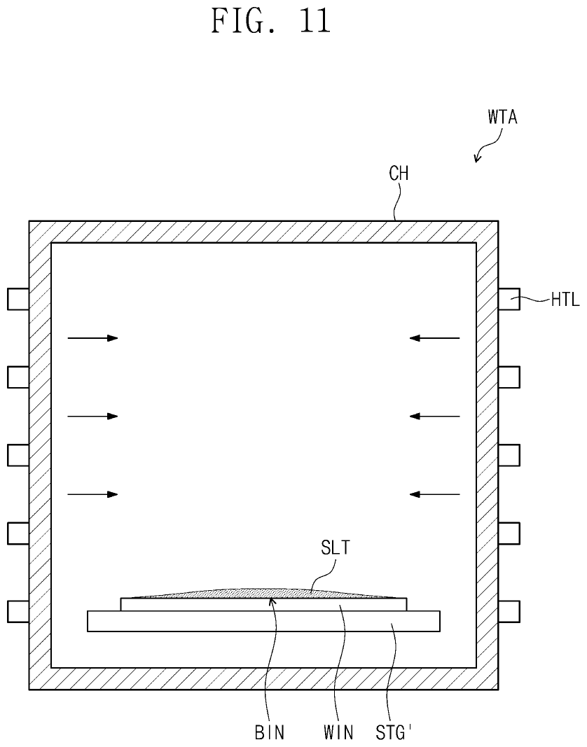

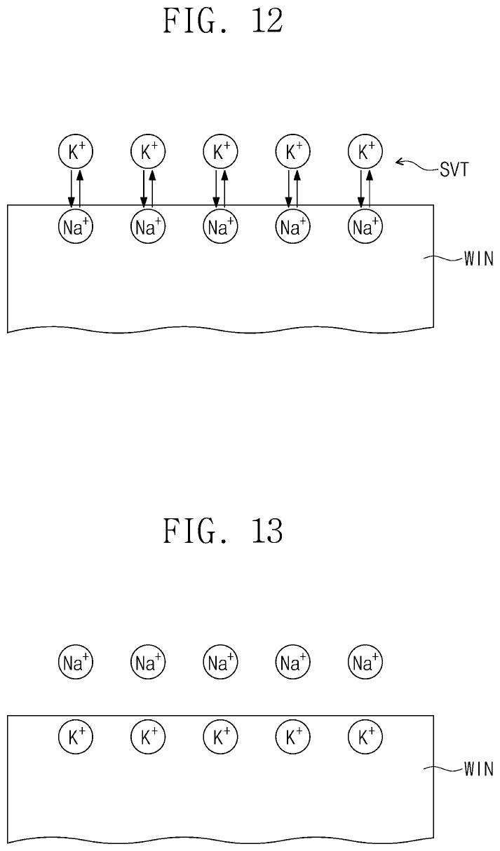

FIG. 11 is a schematic view illustrating a configuration of a window reinforcing apparatus for the window reinforcing process. FIGS. 12 and 13 are schematic views for explaining the reinforcing process of the window illustrated in FIG. 11.

Referring to FIG. 11, the window reinforcing apparatus WTA may further include a heating chamber CH. The window WIN, on which the above-described coating process has been completed, may be placed on a stage STG′ and disposed in the heating chamber CH. Heating lines HTL for heating the heating chamber CH may be disposed on the outer wall of the heating chamber CH. As the heating chamber CH is heated, the window WIN and the reinforcing agent SLT disposed inside the heating chamber CH may be heated. For example, the heating temperature may be in a range of about 370 degrees to about 420 degrees.

Referring to FIG. 12, first ions (Na⁺) may be disposed on the surface of the window WIN, and the reinforcing agent SLT may include second ions (K⁺).

Referring to FIGS. 12 and 13, an ion exchange phenomenon may be generated according to the heating temperature. According to the heating temperature, the second ions (K⁺) may be moved to the surface of the window WIN, and the first ions (Na⁺) may be moved to the outside of the window WIN. As the second ions (K⁺) are disposed on the window WIN, a reinforcing layer may be formed on the surface of the window WIN. Therefore, the surface of the window WIN may be reinforced. As the second ions (K⁺) are disposed on the window WIN, compressive stress of the surface of the window WIN may be increased.

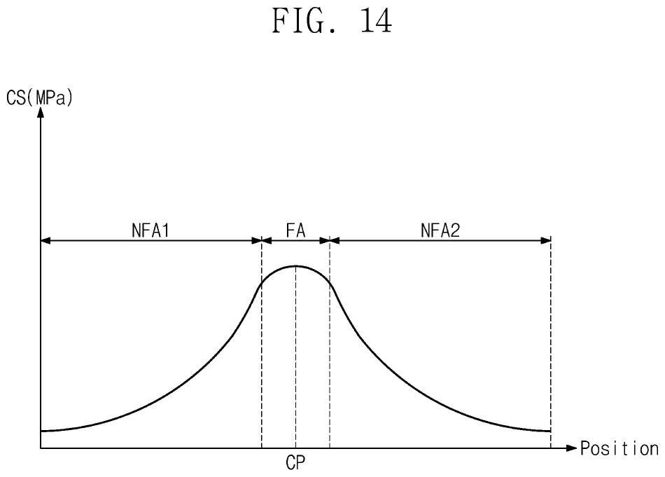

FIG. 14 is a schematic view illustrating a graph of the compressive stress formed on the surface of the window.

Referring to FIGS. 9 and 14, compressive stress CS of the surface of the window WIN may be proportional to the coating amount of the reinforcing agent SLT applied to the surface of the window WIN. Therefore, the compressive stress CS of the surface of the window WIN may be expressed by Equation (2).

CS(x)=(L−2x)/2V(x) (2)

where CS may represent the compressive stress CS of the surface of the window WIN. CS(x) may represent the compressive stress CS of the surface of the window WIN at the position of the corresponding coordinate.

In FIG. 14, the vertical axis may represent the compressive stress CS, and the horizontal axis may represent the position on the window WIN with respect to the center point CP of the window WIN.

As described above, the coating amount may be reduced from the center point CP of the window WIN toward sides of the window WIN. Therefore, the compressive stress CS may also be reduced from the center point CP of the window WIN toward the sides of the window WIN. As a result, the compressive stress CS of the folding region FA may be greater than the compressive stress CS of the first and second non-folding regions NFA1 and NFA2.

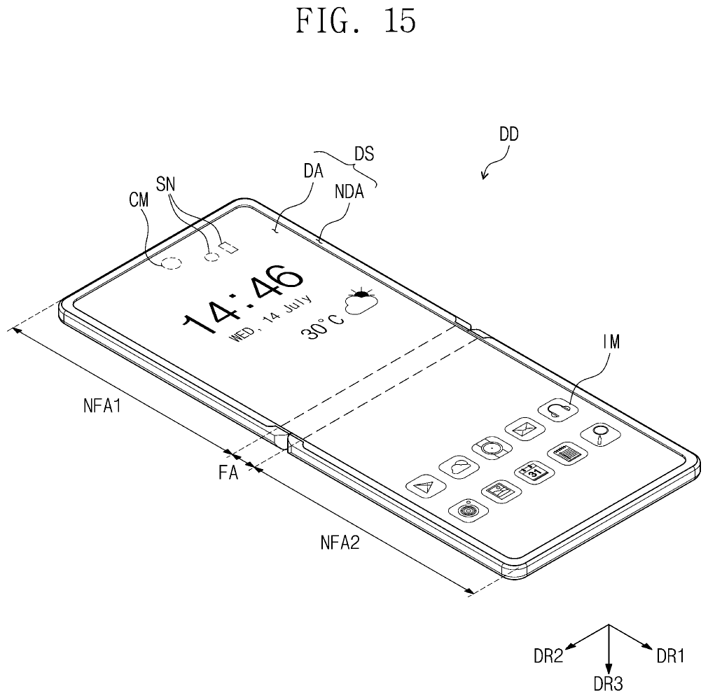

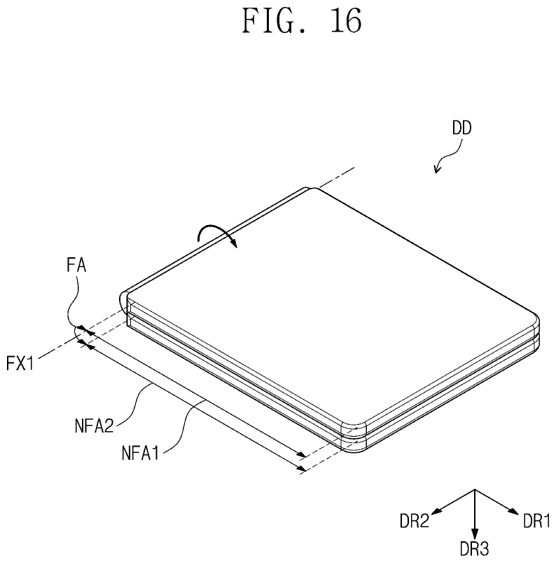

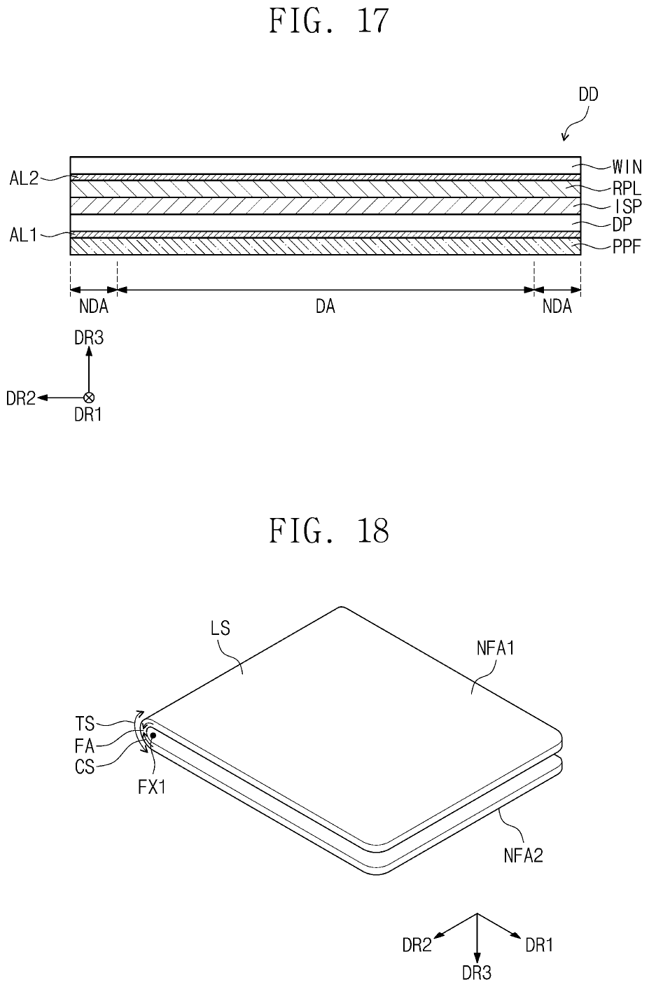

FIG. 15 is a schematic view illustrating a display device that includes the window manufactured by the window reinforcing apparatus including the components illustrated in FIGS. 1 to 11. FIG. 16 is a schematic view illustrating a folding state of the display device illustrated in FIG. 15.

Referring to FIG. 15, a display device DD may have a rectangular shape that has long sides extending in a first direction DR1 and short sides extending in a second direction DR2. However, the embodiment of the disclosure is not limited thereto, and the display device DD may have various shapes such as a circle and a polygon. The display device DD may be a flexible electronic apparatus.

The display device DD may include a folding region FA and non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged in the first direction DR1.

The first non-folding region NFA1, the folding region FA, and the second non-folding region NFA2 may correspond to the first non-folding region NFA1, the folding region FA, and the second non-folding region NFA2, respectively, which are illustrated in FIG. 9.

The upper surface of the display device DD may be defined as a display surface DS and may have a plane defined by the first direction DR1 and the second direction DR2. Through the display surface DS, images IM generated in the display device DD may be provided to a user.

The display surface DS may include a display region DA and a non-display region NDA around the display region DA. The display region DA may display an image, and the non-display region NDA may not display an image. The non-display region NDA may surround the display region DA, and may define the edge of the display device DD printed in a certain color.

The display device DD may include sensors SN and at least one camera CM. The sensors SN and the camera CM may be adjacent to the edge of the display device DD. The sensors SN and the camera CM may be arranged in the display region DA adjacent to the non-display region NDA. The sensors SN and the camera CM may be arranged in the first non-folding region NFA1, but the positions at which the sensors SN and the camera CM are arranged are not limited thereto.

For example, the sensors SN may include proximity luminance sensors, but the types of the sensors SN are not limited thereto. The camera CM may capture an external image.

Referring to FIG. 16, the display device DD may be a folding-type (foldable) display device DD that is folded or unfolded. For example, the folding region FA may be bent about a folding axis FX1 parallel to the second direction DR2, and thus, the display device DD may be folded. The folding axis FX1 may be defined as a short axis parallel to the short sides of the display device DD.

In case that the display device DD is folded, the display device DD may be in-folded. Accordingly, the first non-folding region NFA1 and the second non-folding region NFA2 may face each other, and the display surface DS may not be exposed to the outside.

FIG. 17 is a schematic view illustrating, as an example, the cross-section of the display device illustrated in FIG. 15.

For example, FIG. 17 illustrates the cross-section of the display device DD when viewed in the first direction DR1.

Referring to FIG. 17, the display device DD may include a display panel DP, an input sensing part ISP, a reflection preventing layer RPL, a window WIN, a panel protective film PPF, and first and second adhesive layers AL1 and AL2.

The display panel DP may be a flexible display panel. The display panel DP according to an embodiment of the disclosure may be a light emitting display panel, but is not particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include quantum dots, quantum rods, and the like. Hereinafter, the display panel DP is described as the organic light emitting display panel.

The input sensing part ISP may be disposed on the display panel DP. The input sensing part ISP may include sensing parts (not shown) for sensing an external input by a capacitive method. The input sensing part ISP may be manufactured directly on the display panel DP in case that the display device DD is manufactured. However, the embodiment of the disclosure is not limited thereto, and the input sensing part ISP may be manufactured in the form of a panel independently from the display panel DP and attached to the display panel DP by an adhesive layer.

The reflection preventing layer RPL may be disposed on the input sensing part ISP. The reflection preventing layer RPL may be manufactured directly on the input sensing part ISP in case that the display device DD is manufactured. However, the embodiment of the disclosure is not limited thereto, and the reflection preventing layer RPL may be manufactured in the form of a separate panel and attached to the input sensing part ISP by an adhesive layer.

The reflection preventing layer RPL may be defined as a film that prevents reflection of external light. The reflection preventing layer RPL may reduce reflectivity of external light which is incident toward the display panel DP from above the display device DD. The external light may not be recognized by a user due to the reflection preventing layer RPL.

In case that the external light traveling toward the display panel DP is reflected from the display panel DP and provided back to an external user, the user may recognize the external light as in a case of a mirror. In order to prevent the above-described phenomenon, the reflection preventing layer RPL may include, for example, color filters that display a same color as pixels of the display panel DP.

The color filters may filter the external light to display a same color as the pixels. The external light may not be recognized by the user. However, the embodiment of the disclosure is not limited thereto, and the reflection preventing layer RPL may include a phase retarder and/or a polarizer for reducing the reflectivity of the external light.

The window WIN may be disposed on the reflection preventing layer RPL. The window WIN may protect the display panel DP, the input sensing part ISP, and the reflection preventing layer RPL from scratch and impact from the outside. The window WIN may be the same as the window WIN manufactured by the window reinforcing apparatus WTA described above.

The panel protective film PPF may be disposed below the display panel DP. The panel protective film PPF may protect a lower portion of the display panel DP. The panel protective film PPF may include a flexible plastic material such as polyethyleneterephthalate (PET).

A first adhesive layer AL1 may be disposed between the display panel DP and the panel protective film PPF, and the display panel DP and the panel protective film PPF may be bonded to each other by the first adhesive layer ALL A second adhesive layer AL2 may be disposed between the window WIN and the reflection preventing layer RPL, and the window WIN and the reflection preventing layer RPL may be bonded to each other by the second adhesive layer AL2.

FIG. 18 is a schematic view illustrating a folding state of the window illustrated in FIG. 17.

Referring to FIG. 18, in case that the window WIN is folded, tensile stress TS may be generated on a rear surface LS of the window WIN that is convexly curved outward in the folding region FA. As the tensile stress TS increases, cracks may occur in the window WIN, and this may damage the window WIN.

In an embodiment of the disclosure, the surface of the window WIN is reinforced, and the compressive stress CS of the surface of the window WIN may be enhanced. For example, in FIG. 18, the compressive stress CS of the rear surface LS of the window WIN may be enhanced.

As described above, the compressive stress CS of the folding region FA may be greater than that of the first and second non-folding regions NFA1 and NFA2. The compressive stress CS may attenuate the tensile stress TS. For example, a compressive force may act on a portion to be stretched.

The compressive stress CS attenuates the tensile stress TS, and thus, cracks may not occur in the rear surface LS of the folding region FA of the window WIN. Therefore, in case that the window WIN is folded, damage to the window WIN may be prevented by the compressive stress CS.

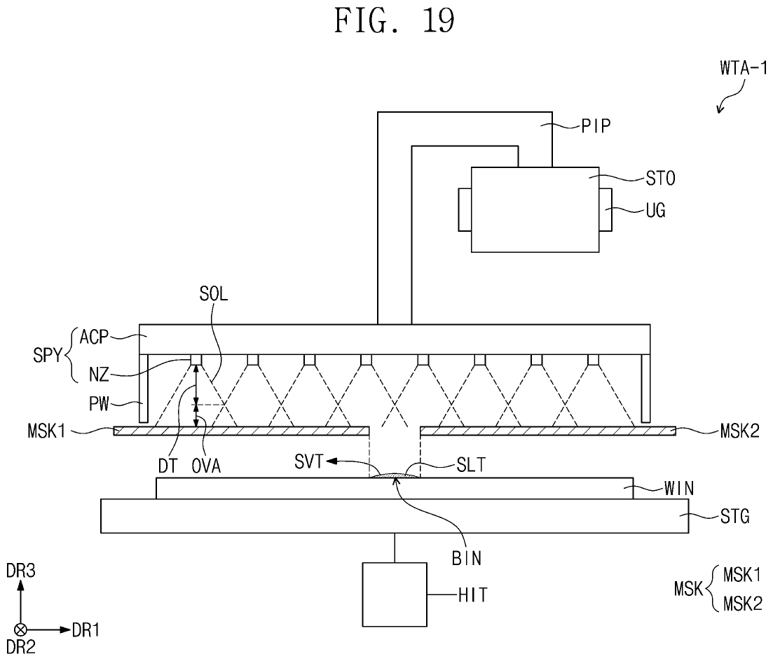

FIG. 19 is a schematic view illustrating a configuration of a window reinforcing apparatus according to an embodiment of the disclosure.

For example, FIG. 19 illustrates a schematic side view corresponding to FIG. 6.

Referring to FIG. 19, a window reinforcing apparatus WTA-1 may further include partition walls PW. The partition walls PW may be disposed at the edge of a spray part SPY and extend toward first and second masks MSK1 and MSK2. The partition walls PW may block a solution SOL sprayed to the outside of the spray part SPY. Therefore, the solution SOL may not be provided to the outside of the spray part SPY by the partition walls PW, but may be sprayed downward.

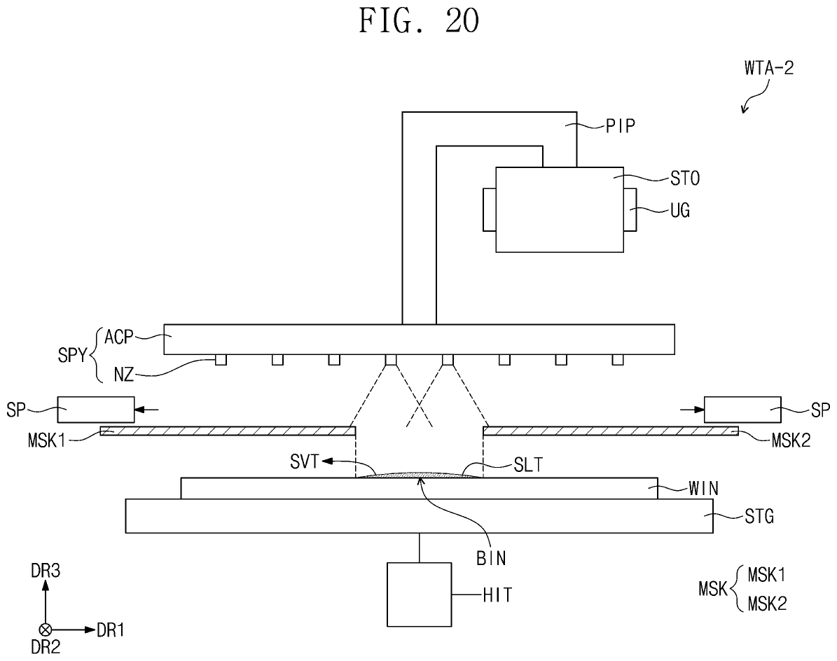

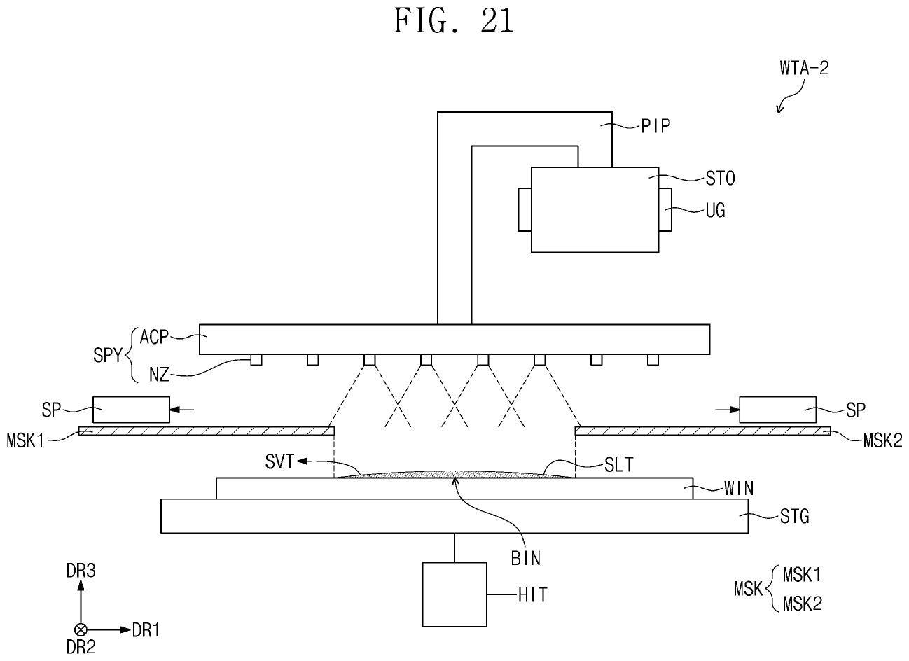

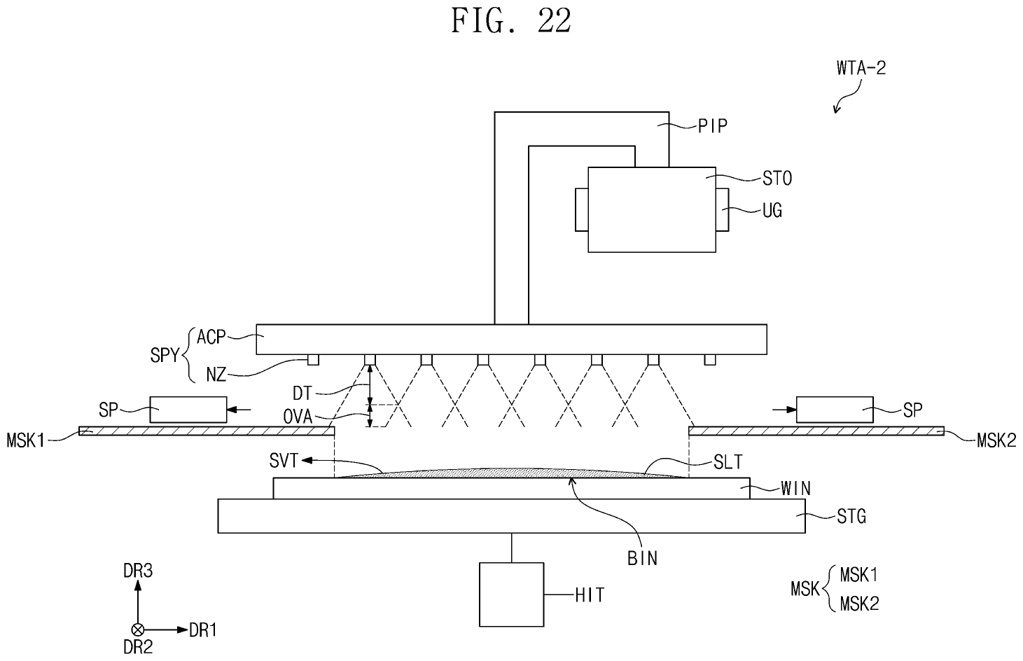

FIGS. 20 to 22 are schematic views illustrating operations of a window reinforcing apparatus according to an embodiment of the disclosure.

For example, FIGS. 20 to 22 illustrate schematic side views corresponding to FIGS. 7 to 9.

Referring to FIGS. 20 to 22, in a window reinforcing apparatus WTA-2, nozzles NZ may be sequentially operated according to the movements of a first mask MSK1 and a second mask MSK2. The operation of the nozzles NZ may be defined as the operation of the nozzles NZ that spray the solution.

In case that the first mask MSK1 and the second mask MSK2 move away from each other in a first direction DR1, a solution SOL may be sprayed sequentially from the nozzles NA exposed between the first mask MSK1 and the second mask MSK2. Therefore, the solution SOL may be sprayed sequentially from the nozzles NZ provided in the central portion.

According to the embodiment of the disclosure, the reinforcing agent is applied thicker on the folding portion of the window, and thus, the compressive stress on the folding portion of the window may be increased. As the compressive stress on the folding portion of the window is increased, damage to the window may be prevented in case that the display device is folded.

Although not illustrated, the window reinforcing apparatus WTA-2 may include sensors, which are disposed on the lower surface of a spray part SPY to sense movements of the first mask MSK1 and the second mask MSK2, and a control part, which sequentially drives the nozzles NZ according to the movements of the first mask MSK1 and the second mask MSK2.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A window reinforcing apparatus comprising:
a spray part which sprays a solution downward;
a plurality of masks which are disposed below the spray part and move in a first direction;
a storage part which is disposed above the spray part, stores the solution, and provides the solution to the spray part; and
a stage disposed below the plurality of masks.

2. The window reinforcing apparatus of claim 1, further comprising:
at least one ultrasonic wave-generating part disposed on an outer wall of the storage part.

3. The window reinforcing apparatus of claim 1, further comprising:
a stirrer which is disposed on a bottom surface of the storage part in an inner space of the storage part and rotates.

4. The window reinforcing apparatus of claim 1, wherein the spray part comprises:
an accommodation part which has a flat plate shape defined by the first direction and a second direction intersecting the first direction and stores the solution provided from the storage part; and
a plurality of nozzles which are disposed below the accommodation part and spray the solution downward.

5. The window reinforcing apparatus of claim 4, wherein the nozzles are arranged in the first direction and the second direction.

6. The window reinforcing apparatus of claim 4, wherein
the solution is sprayed at a certain spray angle from each of the nozzles, and
the plurality of masks are disposed to overlap regions in which the solutions sprayed from the nozzles overlap each other in a plan view.

7. The window reinforcing apparatus of claim 1, wherein
the plurality of masks comprise a first mask and a second mask which are arranged in the first direction and move in the first direction, and
the solution sprayed from the spray part passes through between the first mask and the second mask which move away from each other in the first direction, and is provided to a window disposed on the stage.

8. The window reinforcing apparatus of claim 7, wherein the stage heats the window to a temperature in a range of about 150 degrees to about 180 degrees.

9. The window reinforcing apparatus of claim 7, wherein the solution comprises:
a solvent; and
a reinforcing agent dissolved in the solvent.

10. The window reinforcing apparatus of claim 9, wherein
the solvent comprises a water, and
the reinforcing agent comprises a potassium nitrate.

11. The window reinforcing apparatus of claim 9, further comprising:
a plurality of binders precipitated in the solution,
wherein the plurality of binders comprise a plurality of metal oxide particles.

12. The window reinforcing apparatus of claim 9, wherein in case that the solution is provided on a surface of the window,
the solvent is evaporated, and
the surface of the window is coated with the reinforcing agent.

13. The window reinforcing apparatus of claim 12, wherein a thickness of the reinforcing agent provided on the surface of the window is reduced gradually from a central portion of the window toward sides of the window in the first direction.

14. The window reinforcing apparatus of claim 12, further comprising:
a camera which is disposed above the stage and captures an image of the surface of the window coated with the reinforcing agent.

15. The window reinforcing apparatus of claim 12, further comprising:
a heating chamber in which the window coated with the reinforcing agent is disposed and the reinforcing agent is heated to a temperature in a range of about 370 degrees to about 420 degrees.

16. The window reinforcing apparatus of claim 15, wherein compressive stress of the window is determined by the following equation,
CS(x)=(L−2x)/2V(x)
where x represents an X-axis coordinate value spaced apart from a center point of the window with respect to the first direction, the X axis is defined as extending in the first direction on the surface of the window, CS represents the compressive stress, L represents a length of the window in the first direction, and V represents speeds of the first and second masks.

17. The window reinforcing apparatus of claim 7, further comprising:
a plurality of suction parts disposed above the first and second masks.

18. The window reinforcing apparatus of claim 7, wherein
the spray part comprises a plurality of nozzles which spray the solution toward the window, and
in case that the first mask and the second mask move away from each other in the first direction, the solution is sprayed sequentially from the nozzles exposed between the first mask and the second mask.

19. The window reinforcing apparatus of claim 1, further comprising:
a partition wall which is disposed on an edge of the spray part and extends toward the first and second masks.

20. A window reinforcing apparatus comprising:
a spray part which sprays a solution having a reinforcing agent downward;
a first mask and a second mask which are disposed below the spray part and move in a first direction; and
a stage disposed below the first and second masks, wherein
the solution sprayed from the spray part passes through between the first mask and the second mask which move away from each other in the first direction, and is provided to a window disposed on the stage, and
a thickness of the reinforcing agent provided on a surface of the window is reduced gradually from a central portion of the window toward sides of the window in the first direction.
